(19) United States
(12) Patent Application Publication
(10) Pub. No.: US 2009/0323302 A1
(43) Pub. Date: Dec. 31, 2009

(54) Thermal relay

(75) Inventors: Yukinari Furuhata, Konosu-shi (JP); Fumihiro Morishita, Konosu-shi (JP); Takeo Kamosaki, Konosu-shi (JP)

Correspondence Address: KANESAKA BERNER AND PARTNERS LLP, 1700 DIAGONAL RD, SUITE 310, ALEXANDRIA, VA, 22314-2848, US

(73) Assignee: FUJI ELECTRIC FA COMPONENTS & SYSTEMS CO., LTD., Tokyo (JP)

(21) Appl. No.: 12/385,929

(22) Filed: Apr. 24, 2009

(30) Foreign Application Priority Data
Jun. 26, 2008 (JP) 2008-166968

(51) Int. Cl. H05K 7/00

(52) U.S. Cl. 361/819

(57) ABSTRACT

A thermal relay includes an outer casing; an adjusting dial for adjusting a setting current value; and a cover for avoiding an erroneous operation. The cover is attached to the outer casing to cover the adjusting dial. A chamfer is provided on each of a peripheral surface of a back surface of the cover and a peripheral surface of a top surface of the adjusting dial. The chamfer on the peripheral surface of the back surface of the cover and the chamfer on the peripheral surface of the top surface of the adjusting dial are engaged with each other.

### BACKGROUND OF THE INVENTION AND RELATED ART STATEMENT

The present invention relates to a thermal relay (a thermally operated overload relay) for use in combination with an electromagnetic contactor, and in particular, to a structure for avoiding erroneous operation of an adjusting dial of the thermal relay.

First, a conventional structure of a thermal relay will be described with reference to FIG. 14. Referring to FIG. 14, reference numeral 101 denotes an outer casing made of a molded resin, 102 denotes a main bimetal that bends with heat generated by a heater connecting to a main circuit, 103 denotes a shifter coupled to a free end of the main bimetal 102, 104 denotes a release lever that moves following displacement of the shifter 103, 105 denotes an inversion operation mechanism for opening and closing a contact, 106 denotes a normally closed contact including a fixed contact point 106a and a movable contact point 106b, 107 denotes a normally opened contact including a fixed contact point 107a and a movable contact point 107b provided on a movable contact piece, 108 denotes an adjusting link that is supported on a slot 101a of the outer casing 101 at one end thereof and connected to a base end of the release lever 104 at a supporting point 104a, and 109 denotes an adjusting dial for adjusting an operation current.

The inversion operation mechanism 105 comprises a swinging movable plate 111 resting on and supported by a V-groove 110a of a support piece 110 with a configuration of approximately a letter U, a tension spring 112 extending between a tip portion 111a of the movable plate 111 and a hook section 110b of the support piece 110, and a driver lever 113 with a configuration of a letter L driving the normally opened contact made of an insulator protruding backwards from the movable plate 111. The movable contact point 106a of the normally closed contact 106 is attached to a tip portion of the movable plate 111. The fixed contact point 106b of the normally closed contact 106 is attached to a contact support piece 114 with a structure of a leaf spring fixed to a bottom part of the outer casing 101 at one end of the support piece and disposed horizontally.

A tension spring 112 includes a coil spring portion 112a, a projection 112b projecting at a central part of the tension spring 112, and hook portions at both ends of the tension spring, all being formed of a wire of spring steel. In an ordinary state of this construction as shown in FIG. 14, the movable plate 111 of the inversion operation mechanism 105 is tilting clockwise from a neutral position receiving a spring force from the tension spring 112 and pushing the movable contact point 106a of the normally closed contact 106 against the fixed contact point 106b to hold the contact in an ON state. In this state, the normally opened contact 107 is in an OFF state.

When an overcurrent flows through the main circuit, the main bimetal 102 is heated and bent, and the free end thereof displaces to move the shifter 103 to the right. The release lever 104 thus swings around the support point 104a. At this moment, the protrusion 112b of the tension spring 112 of the inversion operation mechanism 105 is pushed upwards by the release lever 104. When the displacement of the tension spring 112 exceeds a dead point of the movable plate 111, the movable plate 111 is abruptly driven to be inverted to separate the movable contact point 106a of the normally closed contact 106 from the fixed contact point 106b, and the drive lever 113 pushes the movable contact piece with the movable contact point 107b attached thereon to contact the movable contact point 107b with the fixed contact point 107a to turn ON the contact (Patent Document 1, for example).

Patent Document 2 discloses a structure for avoiding an erroneous operation of an adjusting dial of a thermal relay. This conventional technique is described with reference to FIG. 15. Referring to FIG. 15, in order to avoid an erroneous operation, the adjusting dial 109 is disposed at a deeper place than the top surface of the outer casing 101. The top surface of the outer casing 101 is covered by a rather thick indication cover 117 with a thermal relay type and terminal symbols punched or printed thereon, as shown in FIG. 15. Through the indication cover 117 and the outer casing 101, an adjusting dial insertion hole 101b is formed for inserting the adjusting dial 109 into the outer casing 101. A dial cover 116 is formed in a configuration of a thick disk with an engaging groove 116a formed on the peripheral surface thereof and has a grip 118 with a shape of a letter L on the top surface thereof.

A through hole 119 is formed at the tip portion of the grip 118 for passing a metal wire therethrough. A construction is known in which at the time of covering the adjusting dial 109 with the dial cover 116, the dial cover 116 is inserted into the hole 101b of the indication cover 117 for inserting the adjusting dial and put on an engaging protrusion 117a projecting inward of the hole 101b. Then, the dial cover 116 is pressed towards the adjusting dial 109, deforming the engaging protrusion 117a to engage the engaging protrusion 117a with the engaging groove 116a.

Patent Document 1: Japanese Unexamined Patent Application Publication No. 2001-160346 corresponding to U.S. Pat. No. 6,459,355

Patent Document 2: Japanese Unexamined Patent Application Publication No. H7-254342

In the conventional structure for avoiding an erroneous operation on the adjusting dial of a thermal relay as described in Patent Document 2, the adjusting dial itself is not held. As a consequence, when the thermal relay is subjected to vibration in an operation environment, the vibration is transmitted to the adjusting dial, which in turn changes a setting value of the adjusting dial. Therefore, an erroneous operation may be committed by a worker in the operation site.

The present invention has been made in view of the above issuers, and an object of the invention is to provide a thermal relay in which the adjusting dial is held without variation of a setting value of the adjusting dial regardless of undergoing vibration, avoiding an erroneous operation.

Further objects and advantages of the invention will be apparent from the following description of the invention.

### SUMMARY OF THE INVENTION

To attain the above object, a thermal relay of the invention comprises an outer casing; an adjusting dial for adjusting a setting current value; and a cover for avoiding an erroneous operation, the cover being attached to the outer casing to cover the adjusting dial, wherein a chamfer or tilted surface is provided on each of a peripheral surface of a back of the cover for avoiding an erroneous operation of the adjusting dial and a peripheral surface of a top surface of the adjusting dial, and the chamfer on the peripheral surface of the back of the cover and the chamfer on the peripheral surface of the top surface of the adjusting dial are engaged with each other (a first aspect).

Preferably, at least one of the chamfer on the peripheral surface of the back of the cover and the chamfer on the peripheral surface of the top surface of the adjusting dial is a roughened surface (a second aspect).

The cover for avoiding an erroneous operation of the adjusting dial is provided on the back surface thereof with a damper (a rubber material, a cushion material or the like) that presses and fixes the adjusting dial when the cover is closed (a third aspect).

An arm is provided on a front surface of the cover for avoiding an erroneous operation of the adjusting dial, the arm covering an adjusting groove for adjusting a setting current value of the adjusting dial (a fourth aspect).

Advantageously, the arm provided on the front surface of the cover for avoiding an erroneous operation of the adjusting dial is made to contact the adjusting dial utilizing flexibility of the arm, to thereby press and fix the adjusting dial (a fifth aspect).

Advantageously, the cover for avoiding an erroneous operation of the adjusting dial is provided with a hole, formed around the arm, for visually recognizing a printed surface on a top surface of the adjusting dial for adjusting a setting current value (a sixth aspect).

Advantageously, a back surface of the arm provided on the surface of the cover for avoiding an erroneous operation of the adjusting dial is a roughened surface (a seventh aspect).

In another aspect of the invention, a thermal relay comprises an outer casing; an adjusting dial for adjusting a setting current value; and a cover for avoiding an erroneous operation, the cover being attached to the outer casing to cover the adjusting dial, wherein a peripheral surface of a back surface of the cover for avoiding an erroneous operation of the adjusting dial is press-fitted to a peripheral surface of a top surface of the adjusting dial to fix the adjusting dial with the cover (a eighth aspect).

By provision of the cover for avoiding an erroneous operation of the adjusting dial in the above-described construction, the adjusting dial is stably held without variation in a setting value of the adjusting dial, avoiding an erroneous operation.

### BRIEF DESCRIPTION OF THE DRAWINGS

FIG. 1 is a perspective view showing a cover and a casing in a structure for avoiding an erroneous operation of an adjusting dial according to the invention.

FIG. 2 is a perspective view showing the cover and the casing in the structure for avoiding an erroneous operation of an adjusting dial shown in FIG. 1.

FIG. 3 is a perspective view showing a back surface of the cover of the structure for avoiding an erroneous operation of an adjusting dial shown in FIG. 1.

FIG. 4 is an enlarged perspective view of the adjusting dial shown in FIG. 1.

FIG. 5 is a plan view of the adjusting dial shown in FIG. 4.

FIG. 6 is a sectional view cut along the line 6-6 of the cover shown in FIG. 1.

FIG. 7 is an exploded perspective view of a cover and a casing in a second embodiment according to the invention.

FIG. 8 is a perspective view showing a back surface of the cover in the structure for avoiding an erroneous operation of the adjusting dial shown in FIG. 7.

FIG. 9 is an enlarged perspective view of the adjusting dial shown in FIG. 7.

FIG. 10 is a sectional view cut along line 10-10 of the cover shown in FIG. 7.

FIG. 11 is a sectional view of a cover of the third embodiment according to the invention.

FIG. 12 is an exploded perspective view of a cover and a casing of the fourth embodiment according to the invention.

FIG. 13 is a sectional view cut along the line 13-13 of the cover shown in FIG. 12.

FIG. 14 is a view of an internal structure of a conventional thermal relay.

FIG. 15 is an enlarged view of a structure for avoiding an erroneous operation in a conventional example.

### DETAILED DESCRIPTION OF PREFERRED EMBODIMENTS

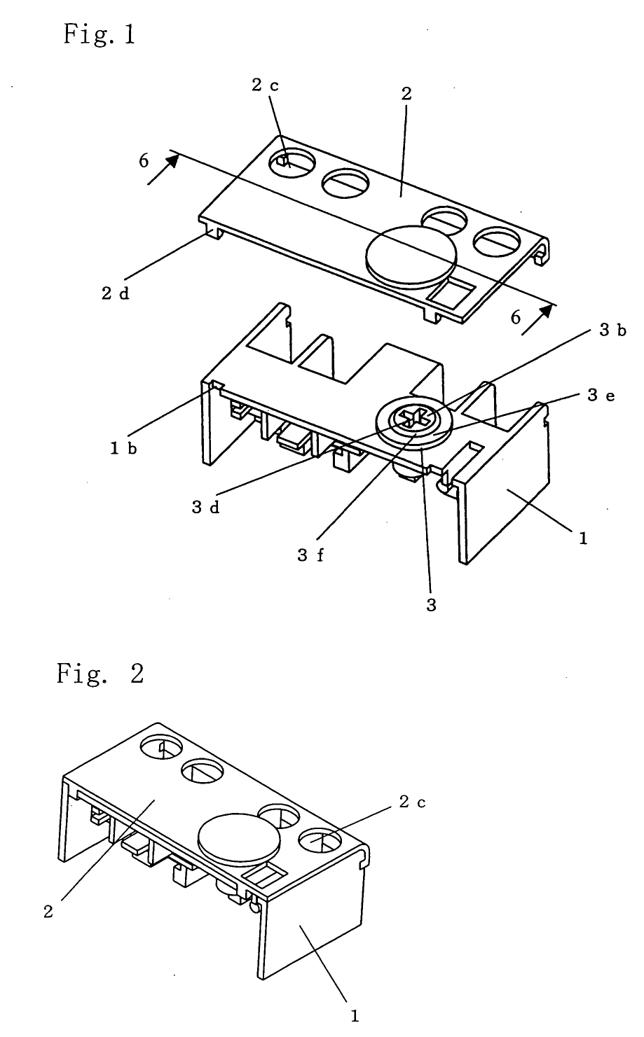

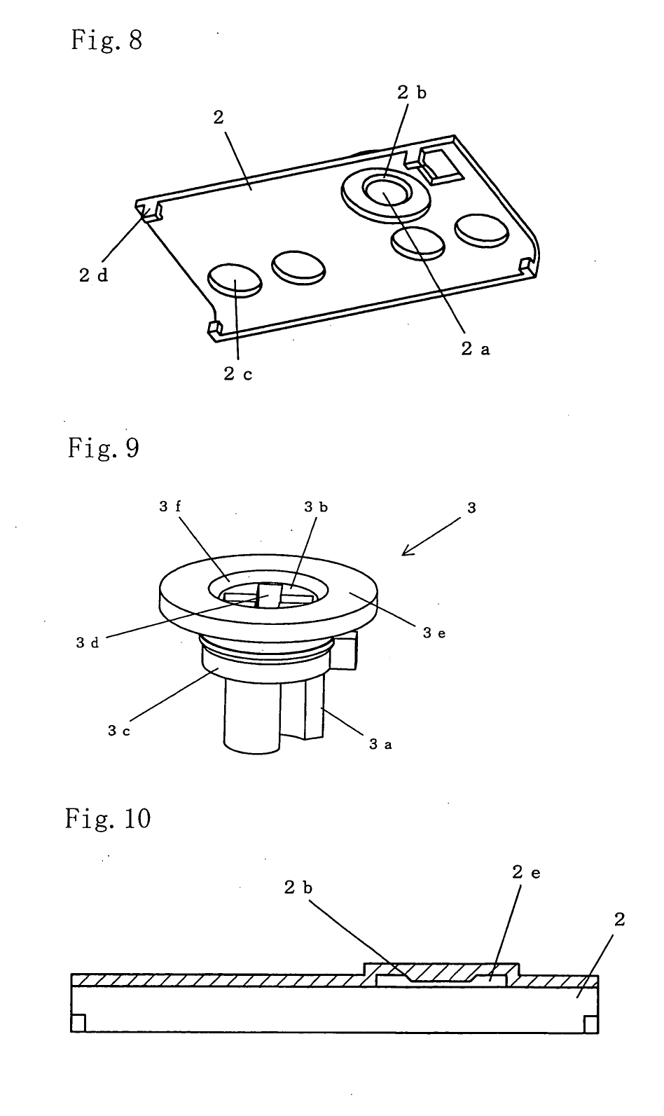

Now, some preferred embodiments of the thermal relay according to the present invention will be described in the following with reference to FIGS. 1 through 13.

FIGS. 1 through 6 show a first embodiment of the invention.

FIG. 1 is an exploded perspective view of a cover and an outer casing in a structure for avoiding an erroneous operation of the adjusting dial according to the invention.

FIG. 2 is a perspective view of the cover and the outer casing in the structure for avoiding erroneous operation of an adjusting dial shown in FIG. 1.

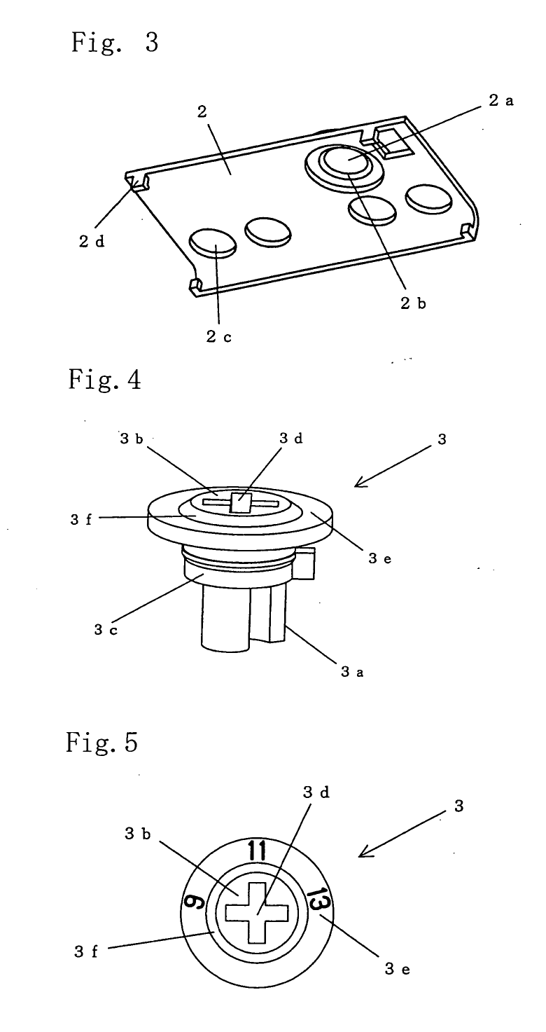

FIG. 3 is a perspective view showing a back surface of the cover of the structure for avoiding an erroneous operation of an adjusting dial of FIG. 1.

FIG. 4 is an enlarged perspective view of the adjusting dial in the structure for avoiding an erroneous operation of an adjusting dial shown in FIG. 1.

FIG. 5 is a plan view of the adjusting dial shown in FIG. 4.

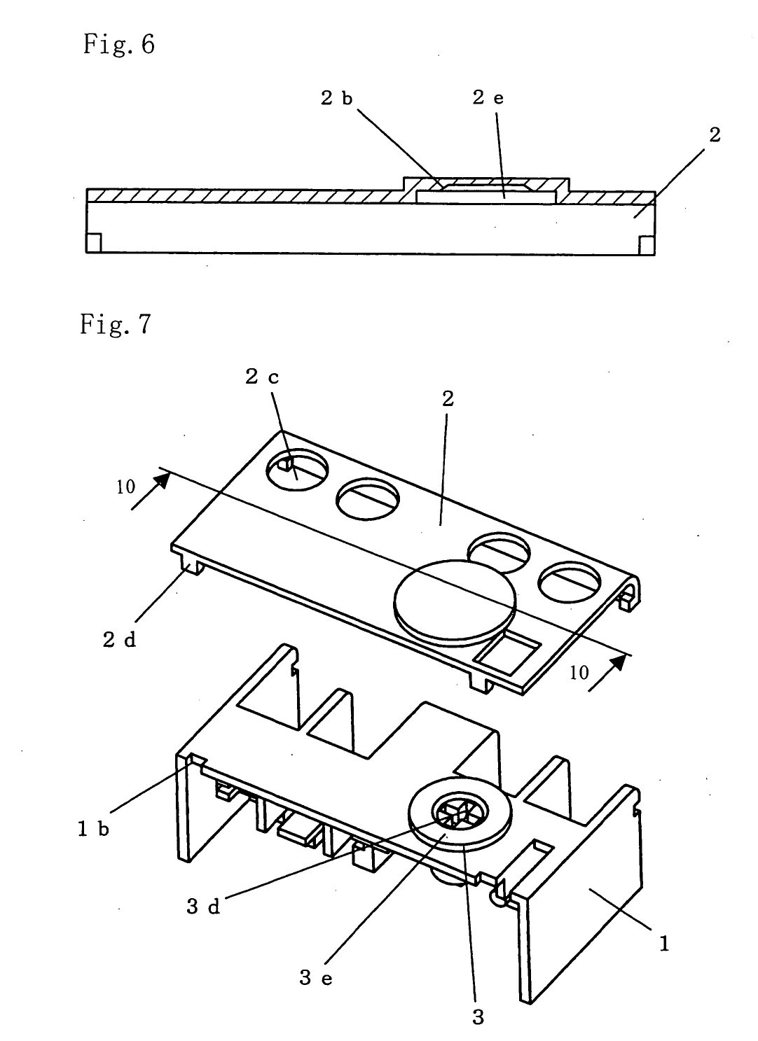

FIG. 6 is a sectional view cut taken along line 6-6 in FIG. 1.

The structure for avoiding an erroneous operation of an adjusting dial shown in FIG. 1 comprises an outer casing 1, a cover 2 for avoiding an erroneous operation made of a transparent material covering the adjusting dial, and an adjusting dial 3 for adjusting a setting current value. The casing 1 shown in FIGS. 1 through 13 is a part of the outer casing 101 shown in FIG. 14.

In the thermal relay shown in FIGS. 1 and 2, auxiliary contact terminals for connecting to an external wiring outside the casing 1 are provided in terminal insertion slot la formed in the outer casing 1. The terminals and the wiring are fastened together using a tool such as a screw driver. The cover 2 is provided with tool insertion holes 2c for allowing fastening with a tool such as a screw driver even in a closed condition of the cover 2.

The cover 2 for avoiding an erroneous operation allows removal from the outer casing 1, and is normally attached to the outer casing 1 by engaging an engaging protrusion 2d formed in the cover with an engaging groove 1b formed on the outer casing 1. The cover 2 can be opened and closed. On the back surface of the cover 2, an adjusting dial fitting recess 2e is formed for engaging with the adjusting dial 3.

The adjusting dial 3 shown in FIG. 4 comprises a current adjusting groove 3d for adjusting a setting current, a top surface 3b with this current adjusting groove formed thereon, a printed surface 3e with a setting current value printed thereon, and a shaft 3c, which has a cam 3a at the bottom thereof.

As illustrated in FIGS. 1 through 6, a chamfer 2b (a tilted surface) is formed on a peripheral surface of the back surface 2a of the cover 2 for avoiding erroneous operation of an adjusting dial as shown in the sectional view of FIG. 6, and a chamfer 3f is formed on a peripheral surface of the top surface 3b with a protruding configuration of the adjusting dial 3 as shown in FIG. 4, so as to engage the chamfer 2b with the chamfer 3f when the cover 2 is closed. Being engaged, the two chamfers 2b and 3f are subjected to a frictional force to fix the adjusting dial.

By roughening at least one of the chamfers 2b and 3f, a larger frictional force is applied. By such a measure, the adjusting dial 3 would not displace by itself regardless of vibration subjected to the adjusting dial and is stably fixed.

FIGS. 7 through 10 show the second embodiment of the invention.

While in the first embodiment as described above, the top surface 3b of the adjusting dial 3 is formed with a protrusion and a chamfer 3f is formed on the peripheral surface of the protrusion, the top surface 3b may be formed with a recess on which a chamfer 3f is formed, and the back surface of the cover 2 for avoiding an erroneous operation of an adjusting dial is formed with a protrusion on which a chamfer 2b is formed, to engage the chamfer 2b with the chamfer 3f, as shown in FIGS. 9 and 10.

FIG. 11 shows the third embodiment of the invention, and is a sectional view of the cover 2 for avoiding an erroneous operation of an adjusting dial. In the embodiments as shown in FIGS. 1 through 10, the chamfers 2b and 3f are formed on the cover 2 and on the adjusting dial 3 and the two chamfers 2b and 3f are engaged with each other to be subjected to a frictional force and fix the adjusting dial. On the other hand, the structure of the adjusting dial 3 shown in FIG. 11 may have either configuration of FIG. 4 or FIG. 5 and comprises a damper 4 on the back surface 2a of the cover 2 for avoiding an erroneous operation of an adjusting dial. When the cover 2 for avoiding an erroneous operation of an adjusting dial is closed, the adjusting dial 3 is pressed and fixed with the damper 4. In this structure, the chamfer 2b on the peripheral surface of the back surface 2a of the cover 2 for avoiding an erroneous operation of an adjusting dial may be eliminated.

Vibration subjected to the adjusting dial in this structure of the third embodiment does not change a setting current value and an erroneous operation is avoided in an operation at a job site.

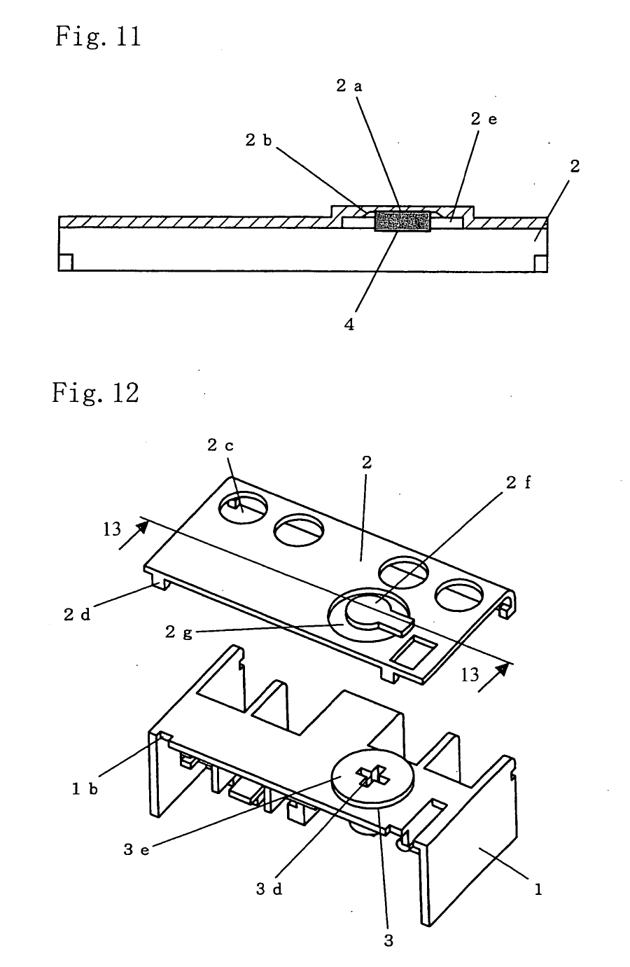

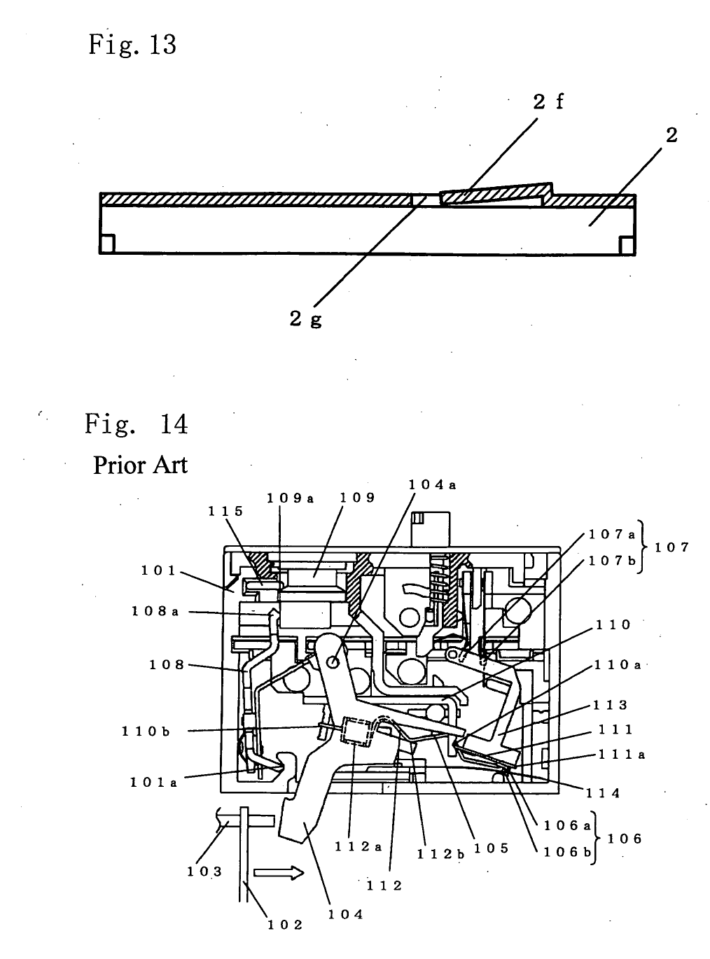

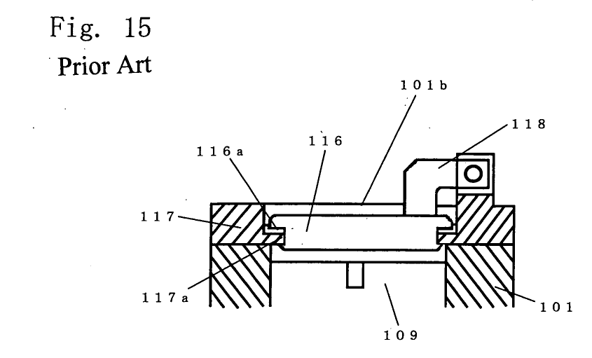

FIGS. 12 and 13 show the fourth embodiment of the invention.

As shown in FIGS. 12 and 13, a hole 2g for visual recognition is provided in the cover 2 for avoiding an erroneous operation of an adjusting dial in order to set a setting current value of the adjusting dial and visually recognize a printed surface 3e for confirming the set value. In addition, an arm 2f is provided at the center region of the groove 3d for adjusting a setting current of the adjusting dial to fix the adjusting dial by a contact therewith in the configuration so as not to disturb visual recognition of the set value printed on the printed surface 3e of the adjusting dial 3. The cover 2 for avoiding an erroneous operation of an adjusting dial in this embodiment is not necessarily transparent different from the ones in the first to third embodiments.

The arm 2f formed on the cover 2 for avoiding an erroneous operation of an adjusting dial is capable of fixing the adjusting dial 3 at the center region of the current adjusting groove 3d by contacting with the adjusting dial 3. The arm 2f is constructed to bend towards the back surface side of the cover 2 for avoiding an erroneous operation of an adjusting dial and to contact the center region of the current adjusting groove 3d and fix the adjusting dial utilizing this flexibility of the arm.

The adjusting dial 3 is more stably fixed by roughening the back surface of the arm 2f provided on the cover 2 for avoiding an erroneous operation of an adjusting dial. This means enhances a frictional force in contact with the center region of the adjusting dial 3 and stably fixes the adjusting dial regardless of continuous vibration subjected to the adjusting dial 3.

Moreover, a damper may be provided on the back surface of the arm 2f formed on the cover 2 for avoiding an erroneous operation of an adjusting dial to fix the adjusting dial, besides the roughening of the back surface of the arm 2f.

In another embodiment, the adjusting dial 3 and the cover 2 for avoiding an erroneous operation of the adjusting dial are press-fitted together by pressing the peripheral surface of the back surface 2a of the cover 2 for avoiding an erroneous operation of an adjusting dial into the peripheral surface of the top surface of the adjusting dial in order to fix the adjusting dial, besides the method of engaging the chamfers 2b and 3f formed on the cover 2 and the adjusting dial 3.

The disclosure of Japanese Patent Application No. 2008-166968 filed on Jun. 26, 2008 is incorporated as a reference.

While the invention has been explained with reference to the specific embodiments of the invention, the explanation is illustrative and the invention is limited only by the appended claims.

What is claimed is:

1. A thermal relay comprising:
an outer casing;
an adjusting dial for adjusting a setting current value; and
a cover for avoiding an erroneous operation, the cover being attached to the outer casing to cover the adjusting dial,
wherein a chamfer is provided on each of a peripheral surface of a back surface of the cover for avoiding the erroneous operation of the adjusting dial and a peripheral surface of a top surface of the adjusting dial, and the chamfer on the peripheral surface of the back surface of the cover and the chamfer on the peripheral surface of the top surface of the adjusting dial are engaged with each other.

2. The thermal relay according to claim 1, wherein at least one of the chamfer of the cover and the chamfer of the adjusting dial is a roughened surface.

3. A thermal relay comprising:
an outer casing;
an adjusting dial for adjusting a setting current value; and
a cover for avoiding an erroneous operation, the cover being attached to the outer casing to cover the adjusting dial,
wherein the cover for avoiding the erroneous operation of the adjusting dial is provided on a back surface thereof with a damper that presses and fixes the adjusting dial when the cover is closed.

4. A thermal relay comprising:
an outer casing;
an adjusting dial for adjusting a setting current value, said adjusting dial having an adjusting groove for adjusting the setting current value; and
a cover for avoiding an erroneous operation, the cover being attached to the outer casing to cover the adjusting dial,
wherein the cover is provided with an arm on a front surface thereof, the arm covering an adjusting groove.

5. The thermal relay according to claim 4, wherein the arm provided on the front surface of the cover contacts the adjusting dial utilizing flexibility of the arm, and presses and fixes the adjusting dial.

6. The thermal relay according to claim 4, wherein the cover for avoiding the erroneous operation of the adjusting dial is provided with a hole, formed around the arm, for visually recognizing a printed surface on a top surface of the adjusting dial.

7. The thermal relay according to claim 4, wherein a back surface of the arm provided on the surface of the cover is a roughened surface.

8. A thermal relay comprising:
an outer casing;
an adjusting dial for adjusting a setting current value; and
a cover for avoiding an erroneous operation, the cover being attached to the outer casing to cover the adjusting dial,
wherein a peripheral surface of a back surface of the cover for avoiding the erroneous operation of the adjusting dial is press-fitted to a peripheral surface of a top surface of the adjusting dial to fix the adjusting dial to the cover.
